(19) United States
(12) Patent Application Publication
(10) Pub. No.: US 2008/0233493 A1
(43) Pub. Date: Sep. 25, 2008

(54) PROCESSES FOR FORMING PARTITION WALLS, COLOR FILTER AND ORGANIC EL

(75) Inventors: Kenji ISHIZEKI, Tokyo (JP); Hideyuki Takahashi, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Asahi Glass Company, Limited, Chiyoda-ku (JP)

(21) Appl. No.: 12/127,993

(22) Filed: May 28, 2008

Related U.S. Application Data
(63) Continuation of application No. PCT/JP2006/323729, filed on Nov. 28, 2006.

(30) Foreign Application Priority Data
Nov. 28, 2005 (JP) 2005-342278

(51) Int. Cl. G03F 7/20

(52) U.S. Cl. 430/7; 430/325; 430/319

(57) ABSTRACT

To provide a process for forming partition walls excellent in the uniformity in thickness of the ink layer even when light exposure is low in the exposure step.

A process for forming partition walls, which comprises a step of coating a substrate with a negative photosensitive composition containing a fluorinated polymer (A) having a side chain containing a fluoroalkyl group (which may have an etheric oxygen atom) and a side chain containing an ethylenic double bond, a drying step, an exposure step and a development step in this order, followed by a post-exposure step.

### TECHNICAL FIELD

The present invention relates to a process for producing partition walls, such as partition walls for a color filter prepared by an ink jet printing technique, partition walls for ITO electrodes for a liquid crystal display device, partition walls for an organic EL display device or partition walls for a circuit wiring board. Further, the present invention relates to a process for forming a color filter and a process for forming an organic EL display device.

### BACKGROUND ART

Heretofore, resist compositions have been used to prepare masks for production of circuits, such as semiconductor integrated circuits (IC) and thin film transistor (TFT) circuits for liquid crystal displays (LCD).

On the other hand, a resist composition has attracted attention also as a material to form a permanent film for e.g. partition walls between pixels of a color filter, partition walls for ITO electrodes for a liquid crystal display device, partition walls between pixels of an organic EL display device or partition walls of a circuit wiring substrate.

For example, in the production of a color filter, so-called an ink jet method has been proposed which employs an ink jet printing technique to jet and apply R (red), G (green) and B (blue) inks within fine pixels. Here, formation of a pixel pattern is carried out by photolithography using a resist composition, and a coating film cured product of the resist composition is utilized as partition walls between pixels.

In the production of a liquid crystal display device, an ink jet method has been proposed wherein an ITO solution is jetted and applied for the formation of ITO (tin-doped indium oxide) electrodes, and formation of an ITO electrode pattern is carried out by photolithography using a resist composition, and a coating film cured product of the resist composition is utilized as partition walls.

In the production of an organic EL display device, an ink jet method has been proposed wherein a solution of a hole transport material or a luminescent material is jetted and applied to form hole transport layers or luminescent layers within fine pixels. Here, formation of a pixel pattern is carried out by photolithography using a resist composition, and a coating film cured product of the resist composition is utilized as partition walls between pixels.

In the production of a circuit wiring substrate, an ink jet method has been proposed wherein a metal solution is jetted and applied for forming circuit wirings. Here, formation of a circuit wiring pattern is carried out by photolithography using a resist composition, and a coating film cured product of the resist composition is utilized as partition walls.

In the ink jet method, it is necessary to prevent e.g. color mixing of inks between adjacent pixels, or to prevent the ITO solution or the metal solution from attaching to or solidifying at portions other than the predetermined regions. Accordingly, the partition walls are required to have repellency against water or an organic solvent constituting the ink jet coating solution, i.e. a so-called water-and-oil repellency.

Patent Document 1 discloses that a photosensitive composition is coated on a substrate, followed by drying, exposure, development and heating treatment, to form partition walls.

Patent Document 1: JP-A-2005-60515

### DISCLOSURE OF THE INVENTION

### Object to be Accomplished by the Invention

However, when an ink was injected by an ink jet method into grooves (dots) formed by the above conventional method, to form an ink layer, the thickness of the ink layer sometimes became non-uniform. If a color filter or an organic EL display device was prepared by using such an ink layer, a so-called edge leakage took place wherein the thickness of the ink layer in the vicinity of partition walls became thin, and the periphery of the partition walls looked white. Such non-uniformity in thickness of the ink layer was particularly distinct when partition walls were formed with low light exposure, while it is desired to lower light exposure in the exposure step in order to increase the resolution of the partition walls.

Therefore, it is an object of the present invention to provide a process for forming partition walls excellent in the uniformity in thickness of the ink layer even when light exposure is low in the exposure step.

### Means to Accomplish the Object

The present invention provides a process for forming partition walls, which comprises a step of coating a substrate with a negative photosensitive composition containing a fluorinated polymer (A) having a side chain containing a fluoroalkyl group (which may have an etheric oxygen atom) and a side chain containing an ethylenic double bond, a drying step, an exposure step and a development step in this order, followed by a post-exposure step.

The fluorinated polymer (A) contained in the negative photosensitive composition of the present invention has a side chain containing a fluoroalkyl group, and it thus has a surface migration characteristic and will migrate to the vicinity of the coating film surface in the drying step. Thus, water-and-oil repellency (repellency against ink) will be developed at the upper surface of partition walls formed of the composition.

Further, the fluorinated polymer (A) has a side chain containing an ethylenic double bond, and thus, it can be cured and fixed at the coating film surface in the exposure step. However, in a case where light exposure in the exposure step is low, there may be a case where some molecules of the fluorinated polymer (A) may not undergo a curing reaction and may remain in the partition walls without being removed from the system in the development step. In the conventional method, such non-reacted remaining molecules are considered to have migrated to dots from the partition walls to contaminate the dots in the heat treatment step which is carried out after the development step.

In the present invention, the process has a post-exposure step after the development step, whereby the curing reaction of the fluorinated polymer (A) is carried out sufficiently thereby to prevent migration of unreacted remaining molecules to dots. Namely, the partition walls are excellent in water-and-oil repellency, and the dots are excellent in water-and-oil affinity. Accordingly, the dots will have high ink wettability, and the ink will uniformly spread within the dots, and the uniformity in thickness of the ink layer thereby formed will be high.

In the present invention, the partition walls will sufficiently be cured by the post-exposure step and will have durability against the solvent in the ink to be used in the ink jet method. Accordingly, curing by a heat treatment step may not necessarily be required.

On the other hand, for the purpose of increasing the heat resistance of the partition walls or removing a volatile component from the partition walls, a heat treatment step may be adopted after the post-exposure step.

In the present invention, the fluorinated polymer (A) preferably has a side chain containing an acidic group. Some molecules of the fluorinated polymer (A) not cured in the exposure step, will be washed off from the surface of the partition walls in the development step, as they have the side chain containing an acidic group, whereby the residual molecules not fixed will scarcely remain in the partition walls. Thus, it is possible to reduce molecules to be migrated to dots at a stage prior to the post-exposure step, such being more effective for improvement of the uniformity in thickness of the ink layer.

Further, the present invention provides a process for forming a color filter, which comprises, after forming partition walls on the substrate by the above-mentioned process, injecting ink by an ink jetting method within regions partitioned by the partition walls, to form pixels.

Further, the present invention provides a process for forming an organic EL display device, which comprises, after forming partition walls on the substrate by the above-mentioned process, injecting ink by an ink jetting method within regions partitioned by the partition walls, to form pixels.

Non-reacted residual molecules scarcely remain in the partition walls, and no migration takes place over a long period of time after forming the device, and the reliability of the device will not be lowered.

### EFFECTS OF THE INVENTION

According to the process of the present invention, it is possible to obtain partition walls excellent in uniformity in thickness of the ink layer even when light exposure is low in the exposure step. Therefore, the process for forming partition walls of the present invention is useful for forming partition walls for a color filter to be prepared by an ink jet coating system, for partition walls for ITO electrodes of a liquid crystal display device, for partition walls for an organic EL display device, or for partition walls for an electronic device, such as partition walls for a circuit wiring substrate.

### BEST MODE FOR CARRYING OUT THE INVENTION

Now, the present invention will be described in further detail. In this specification, “%” means “mass %” unless otherwise specified.

Firstly, the process for forming partition walls of the present invention will be described.

### Coating Step

Firstly, a coating film of a negative photosensitive composition is formed on the surface of a substrate by a known coating film-forming method. The coating film-forming method may, for example, be a spraying method, a roll coating method, a spin coating method or a bar-coating method.

As the substrate, its material is not particularly limited, and it may, for example, be various glass plates; a polyester such as a polyethylene terephthalate; a polyolefin such as polypropylene or polyethylene; a thermoplastic sheet of e.g. a poly(meth)acrylic resin, a polycarbonate, a polymethyl methacrylate or a polysulfone; or a thermosetting plastic sheet of e.g. an epoxy resin or an unsaturated polyester. Particularly, from the viewpoint of the heat resistance, a glass plate or a heat resistant plastic is preferably employed. Further, a transparent substrate is preferred, since the post exposure may be carried out from the rear side (the substrate side) on which no partition walls are formed.

Further, it is also possible to employ a substrate having a black matrix such as a metal black matrix or a resin black matrix formed thereon. In such a case, it is preferred to form partition walls on the black matrix by the process of the present invention.

### Drying Step

Then, the coating film is dried (hereinafter referred to also as prebaking). By the prebaking, the solvent is volatilized, and a coating film having no fluidity will be obtained. The prebaking conditions vary depending on the types and the blending proportions of the respective components, but they are preferably within wide ranges of from 50 to 120° C. for from 10 to 2,000 seconds.

### Exposure Step

Then, exposure is carried out, i.e. the coating film after heated is irradiated with light via a mask having a prescribed pattern. The light to be irradiated may, for example, be visible light, ultraviolet rays, far ultraviolet rays, an excimer laser such as KrF excimer laser, ArF excimer laser, F₂ excimer laser, Kr₂ excimer laser, KrAr excimer laser or Ar₂ excimer laser, X-rays or electron beams. It is preferably light having a wavelength of from 100 to 600 nm, more preferably electromagnetic waves having a distribution within a range of from 300 to 500 nm, particularly preferably i-line (365 nm), h-line (405 nm) or g-line (436 nm).

As an irradiation device, a known super high pressure mercury lamp or deep UV lamp may, for example, be used. Light exposure is preferably within a range of from 5 to 1,000 mJ/cm², more preferably from 50 to 400 mJ/cm². If the light exposure is lower than 5 mJ/cm², curing of partition walls tends to be inadequate, and in the subsequent development or dissolution, peeling is likely to occur, such being undesirable. If the light exposure exceeds 1,000 mJ/cm², it tends to be difficult to obtain a high resolution.

### Development Step

After the exposure step, development is carried out by a developer to remove a non-exposed portion. As such a developer, it is possible to employ an aqueous alkali solution which is made of an alkali, such as an inorganic alkali such as sodium hydroxide, potassium hydroxide, sodium carbonate, sodium silicate, sodium metasilicate or aqueous ammonia, a primary amine such as ethylamine or n-propylamine, a secondary amine such as diethylamine or di-n-propylamine, a tertiary amine such as triethylamine, methyldiethylamine or N-methylpyrrolidone, an alcohol amine such as dimethylethanolamine or triethanolamine, a quaternary ammonium salt such as tetramethylammonium hydroxide, tetraethylammonium hydroxide or choline, or a cyclic amine such as pyrrole or piperidine. Further, an aqueous solution having a proper amount of a water-soluble organic solvent such as methanol or ethanol, a surfactant, or the like, added to the above aqueous alkali solution, may also be used as a developing solution.

The developing time is preferably from 30 to 180 seconds. Further, the developing method may be any method such as a dipping method or a paddle method. After the development, washing with water is carried out, followed by drying with compressed air or compressed nitrogen to remove moisture on the substrate.

### Post-Exposure Step

Then, post-exposure is carried out. The post exposure may be carried out from either the front side on which partition walls are formed or the rear side (the substrate side) on which no partition walls are formed. Otherwise, the exposure may be carried out from both the front and rear sides. In a case where partition walls are formed on a black matrix, it is preferred to carry out the exposure from the front side. The light exposure is preferably at least 50 mJ/cm², more preferably at least 200 mJ/cm², further preferably at least 1,000 mJ/cm², still further preferably at least 2,000 mJ/cm².

As light to be irradiated, ultraviolet rays are preferred, and as a light source, a known super high pressure mercury lamp or high pressure mercury lamp may, for example, be used. Such a light source is preferably employed, since it emits light of at most 600 nm which contributes to curing of partition walls, and emission of light of at most 200 nm which causes decomposition by oxidation of partition walls is thereby little. Further, it is preferred that a quartz tube glass used for a mercury lamp has an optical filter function to shield light of at most 200 nm.

Otherwise, a low pressure mercury lamp may also be used as a power source. However, with a low pressure mercury lamp, the emission intensity of wavelength of at most 200 nm is high, and decomposition by oxidation of partition walls is likely to take place by formation of ozone, and accordingly, it is not desirable to carry out a large quantity of exposure. The light exposure is preferably at most 500 mJ/cm², more preferably at most 300 mJ/cm².

### Heat Treatment Step

Then, heat treatment may be carried out by a heating device such as a hot plate or an oven, preferably at from 150 to 250° C. for from 5 to 90 minutes.

### Formation of Color Filter

In a case where a color filter is to be formed by using the partition walls obtained by the present invention, after forming partition walls by the above process, pixels are formed within dots between the partition walls, by means of an ink jet method.

The ink jet apparatus to be used for forming such pixels is not particularly limited. For example, it is possible to use an ink jet apparatus employing various methods, such as a method of continuously jetting an electrified ink and controlling it by a magnetic field, a method of periodically spraying an ink by using piezoelectric elements, a method of heating ink and intermittently jetting it by utilizing its foaming.

Further, the shape of pixels to be formed by the pixel-forming step of the present invention may be of any known configuration such as a stripe type, a mosaic type, a triangle type or a 4-pixel configuration type.

The ink to be used for forming pixels, mainly comprises a coloring component, a binder resin component and a solvent component.

A water-base ink comprises, as a solvent, water and, if necessary, a water-soluble organic solvent, and as a binder resin component, a water-soluble or water-dispersible resin, and it contains various additives as the case requires.

Whereas, an oil-base ink comprises an organic solvent as the solvent and a resin soluble in the organic solvent, as the binder resin component, and it contains various additives as the case requires.

As the coloring component, it is preferred to employ a pigment or dye excellent in heat resistance, light resistance, etc.

As the binder resin component, a transparent resin excellent in heat resistance is preferred, such as an acrylic resin, a melamine resin or an urethane resin, but it is by no means restricted thereto.

Further, after injecting ink by an ink jet method, if required, it is preferred to carry out a drying step, a heat-curing step or an ultraviolet ray-curing step.

After forming pixels, an overcoat layer may be formed as the case requires. It is preferred that such an overcoat layer is formed for the purpose of improving the surface flatness and for the purpose of preventing an eluent from the ink at partition walls or pixels from reaching to the liquid crystal layer. In a case where such an overcoat layer is to be formed, it is preferred to preliminarily remove the liquid repellency of the partition walls. In a case where the liquid repellency is not removed, the overcoating liquid will be repelled, and a uniform film thickness tends to be hardly obtainable, such being undesirable. The method for removing the liquid repellency of partition walls may, for example, be plasma ashing treatment or optical ashing treatment.

Further, as the case requires, it is preferred to form a photospacer on the black matrix to improve the product quality of the liquid crystal panel to be produced by using a color filter.

### Formation of Organic EL Display Device

In a case where an organic EL display device is to be formed by using partition walls of the present invention, firstly, a transparent electrode of e.g. indium tin oxide is formed by e.g. a sputtering method on a transparent substrate of e.g. glass, and if necessary, the transparent electrode is etched to have a desired pattern. Then, partition walls of the present invention will be formed by the above process. Then, by using an ink jet method, the solutions of a hole transport material and a luminescent material are sequentially applied within dots between the partition walls and dried, to form a hole transport layer and a luminescent layer. Then, an electrode of e.g. aluminum is formed by e.g. a vapor deposition method, whereby pixels for an organic EL display device will be obtained.

Now, the fluorinated polymer (A) in the present invention will be described. In the names of the following specific compounds, “(meth)acrylate” means an acrylate and/or a methacrylate. Likewise, “(meth)acrylic acid” means acrylic acid and/or methacrylic acid; “acrylamide” means acrylamide and/or methacrylamide; and “(meth)acryloyl group” means an acryloyl group and/or a methacryloyl group.

The fluorinated polymer (A) has a side chain containing a fluoroalkyl group (provided that such an alkyl group may have an etheric oxygen atom between carbon atoms) and a side chain containing an ethylenic double bond. The side chain containing a fluoroalkyl group may be formed directly by a polymerization reaction or may be formed by a chemical conversion after the polymerization reaction. Whereas, the side chain containing an ethylenic double bond may be formed by a chemical conversion after the polymerization reaction.

The fluoroalkyl group is an alkyl group having at least one of hydrogen atoms substituted by a fluorine atom, and it may be linear or branched. The carbon number of the fluoroalkyl group is preferably at most 20. The following structures may be mentioned as specific examples of the fluoroalkyl group.

—CF₃, —CF₂CF₃, —CF₂CHF₂, —(CF₂)₂CF₃, —(CF₂)₃CF₃, —(CF₂)₄CF₃, —(CF₂)₅CF₃, —(CF₂)₆CF₃, —(CF₂)₇CF₃, —(CF₂)₈CF₃, —(CF₂)₉CF₃, —(CF₂)₁₁CF₃, —(CF₂)₁₅CF₃, —CF(CF₃)O(CF₂)₅CF₃, —CF(CF₃)OCF₂CF(CF₃)O(CF₂)₂CF₃, —CF(CF₃)OCF₂CF(CF₃)OCF₂CF(CF₃)OCF₂CF(CF₃)O(CF₂)₂CF₃ and —CF (CF₃)O(CF₂)₅CF₃.

The fluoroalkyl group is preferably a perfluoroalkyl group, whereby the water-and-oil repellency will be good. Further, it is preferably a C₄₋₆ perfluoroalkyl group. In such a case, not only a sufficient water-and-oil repellency is imparted, but also the compatibility with another component constituting a negative photosensitive composition together with the fluorinated polymer (A) will be good, whereby when the composition is applied to form a coating film, no coagulation of the fluorinated polymer (A) tends to take place, and it becomes possible to form partition walls having a good outer appearance.

The ethylenic double bond may, for example, be an addition-polymerizable unsaturated group such as a (meth)acryloyl group, an allyl group, a vinyl group or a vinyl ether group. Some or all of hydrogen atoms of such a group may be substituted by a hydrocarbon group. As such a hydrocarbon group, a methyl group is preferred.

The fluorinated polymer (A) of the present invention can be prepared by copolymerizing at least two monomers including a monomer (a1) containing a fluoroalkyl group and a monomer (a2) containing a reactive group and then reacting the obtained copolymer with a compound (z1) containing a functional group capable of being bonded to the above reactive group and an ethylenic double bond.

A monomer represented by the formula 1 is preferred as the monomer (a1) containing a fluoroalkyl group.

CH₂═C(R¹)COOXR^{f} Formula 1

In the formula, R¹ is a hydrogen atom, a methyl group or a trifluoromethyl group, X is a single bond or a C₁₋₆ bivalent organic group containing no fluorine atom, and R^{f} is a fluoroalkyl group.

In the above formula 1, X is preferably a C₂₋₄ alkylene group, from the viewpoint of the availability. Further, R^{f} is preferably a C₄₋₆ perfluoroalkyl group, whereby the compatibility with another component constituting a negative photosensitive composition together with the fluorinated polymer (A) will be excellent.

The following monomers may be mentioned as examples of the monomer represented by the above formula 1:

CH₂═C(R¹)COOR²R^{f}

CH₂═C(R¹)COOR²NR³SO₂R^{f}

CH₂═C(R¹)COOR²NR³COR^{f}

CH₂═C(R¹)COOCH₂CH(OH)R^{f}

Here, R¹ is a hydrogen atom, a methyl group or a trifluoromethyl group, R² is a C₁₋₆ alkylene group, R³ is a hydrogen atom or a methyl group, and R^{f} is a fluoroalkyl group.

Specific examples for R² may, for example, be —CH₂—, —CH₂CH₂—, —CH(CH₃)—, —CH₂CH₂CH₂—, —C(CH₃)₂—, —CH(CH₂CH₃)—, —CH₂CH₂CH₂CH₂—, —CH(CH₂CH₂CH₃)—, —CH₂(CH₂)₃CH₂— and —CH(CH₂CH(CH₃)₂)—.

Specific examples of the polymer represented by the above formula 1 may, for example be a perfluorohexylethyl (meth)acrylate and a perfluorobutylethyl(meth)acrylate.

The above-mentioned monomers may be used alone or in combination as a mixture of two or more of them.

The monomer (a2) containing a reactive group may, for example, be a monomer containing a hydroxyl group, an acid anhydride containing an ethylenic double bond, a monomer containing a carboxyl group or a monomer containing an epoxy group. Here, the monomer (a2) preferably contains substantially no fluoroalkyl group. After the polymerization, the reactive group of the monomer (a2) containing the reactive group will be reacted with the after-mentioned compound (z1) containing a functional group capable of being bonded to the above reactive group and an ethylenic double bond, to form a fluorinated polymer (A) having a side chain containing an ethylenic double bond.

Specific examples of the monomer containing a hydroxyl group may, for example, be 2-hydroxyethyl (meth)acrylate, 2-hydroxypropyl(meth)acrylate, 3-hydroxypropyl(meth)acrylate, 4-hydroxybutyl (meth)acrylate, 5-hydroxypentyl(meth)acrylate, 6-hydroxyhexyl(meth)acrylate, 4-hydroxycyclohexyl (meth)acrylate, neopentyl glycol mono(meth)acrylate, 3-chloro-2-hydroxypropyl(meth)acrylate, glycerol mono(meth)acrylate, 2-hydroxyethyl vinyl ether, 4-hydroxybutyl vinyl ether, cyclohexanediol monovinyl ether, 2-hydroxyethyl allyl ether, N-hydroxymethyl (meth)acrylamide and N,N-bis(hydroxymethyl)(meth)acrylamide.

Further, the monomer containing a hydroxyl group may be a monomer having a polyoxyalkylene chain with a terminal hydroxyl group. It may, for example, be CH₂═CHOCH₂C₆H₈CH₂O(C₂H₄O)ₖH (wherein k is an integer of from 1 to 100, the same applies hereinafter), CH₂═CHOC₄H₈O(C₂H₄O)ₖH, CH₂═CHCOOC₂H₄O(C₂H₄O)ₖH, CH₂═C(CH₃)COOC₂H₄O(C₂H₄O)ₖH or CH₂═CHCOOC₂H₄O(C₂H₄O)ₘ(C₃H₆O)ₙH (wherein m is 0 or an integer of from 1 to 100, and n is an integer of from 1 to 100, provided that m+n is from 1 to 100, the same applies hereinafter), or CH₂═C(CH₃)COOC₂H₄O(C₂H₄O)ₘ(C₃H₆O)ₙH.

Specific examples of the acid anhydride having an ethylenic double bond may, for example, be maleic anhydride, itaconic anhydride, citraconic anhydride, phthalic anhydride, 3-methylphthalic anhydride, methyl-5-norbornene-2,3-dicarboxylic anhydride, 3,4,5,6-tetrahydrophthalic anhydride, cis-1,2,3,6-tetrahydrophthalic anhydride and 2-buten-1-yl succinic anhydride.

Specific examples of the monomer containing a carboxyl group may, for example, be acrylic acid, methacrylic acid, vinyl acetic acid, crotonic acid, itaconic acid, maleic acid, fumaric acid, cinnamic acid and their salts.

Specific examples of the monomer containing an epoxy group may, for example, be glycidyl(meth)acrylate and 3,4-epoxycyclohexylmethyl acrylate.

In the present invention, the fluorinated polymer (A) preferably further has a side chain having an acidic group. Some molecules of the fluorinated polymer (A) which were not cured in the exposure step will readily be washed off from the surface of partition walls in the development step as they have a side chain containing an acidic group, whereby residual molecules not fixed in the partition walls tend to scarcely remain. It is thereby possible to further reduce molecules which otherwise migrate to dots in a stage prior to the post-exposure step, whereby the water-and-oil affinity of the dots between the partition walls will be higher.

As the acidic group, at least one acidic group selected from the group consisting of a carboxyl group, a phenolic hydroxyl group and a sulfonic acid group is preferred.

The side chain containing an acid group may be formed by the polymerization reaction of the monomer (a3) containing an acidic group or may be formed by a chemical conversion after the polymerization reaction.

In a case where a monomer containing a carboxyl group is used as the monomer (a3) containing an acidic group, and a monomer containing a carboxyl group is used also as the above-mentioned monomer (a2) having a reactive group, one having no ethylenic double bond finally introduced and having a residual carboxyl group, will be deemed to be the monomer (a3).

The monomer containing a phenolic hydroxyl group may, for example, be o-hydroxystyrene, m-hydroxystyrene or p-hydroxystyrene. Or, it may be a monomer having at least one hydrogen atom in such a benzene ring substituted by an alkyl group such as a methyl group, an ethyl group or a n-butyl group, an alkoxy group such as a methoxy group, an ethoxy group or a n-butoxy group, a halogen atom, a haloalkyl group having at lease one hydrogen atom of an alkyl group substituted by a halogen atom, a nitro group, a cyano group or an amide group.

The monomer containing a sulfonic acid group may, for example, be vinyl sulfonic acid, styrene sulfonic acid, (meth)allyl sulfonic acid, 2-hydroxy-3-(meth)allyloxypropane sulfonic acid, 2-sulfoethyl (meth)acrylate, 2-sulfopropyl(meth)acrylate, 2-hydroxy-3-(meth)acryloxypropane sulfonic acid, or 2-(meth)acrylamide-2-methylpropane sulfonic acid.

In the process of the present invention, the monomer to be used for the polymerization may contain a monomer (a4) other than the monomer (a1) containing a fluoroalkyl group, the monomer (a2) containing a reactive group and the monomer (a3) containing an acidic group.

Such other monomer (a4) may, for example, be a hydrocarbon type olefin, a vinyl ether, an isopropenyl ether, an allyl ether, a vinyl ester, an allyl ester, a (meth)acrylate, a (meth)acrylamide, an aromatic vinyl compound, a chloroolefin or a conjugated diene. Such a compound may contain a functional group, and the functional group may, for example, be a carbonyl group or an alkoxy group. A (meth)acrylate or a (meth)acrylamide is particularly preferred, since the heat resistance of the partition walls formed from the composition will thereby be excellent.

Further, in order to improve the ink falling property of the coating film, a (meth)acrylate containing a silicone group represented by the following formula, may be incorporated.

—(SiR⁴R⁵—O)n—SiR⁴R⁵R⁶ Formula 2

In the formula, each of R⁴ and R⁵ is independently a hydrogen atom, an alkyl group, a cycloalkyl group or an aryl group, R⁶ is a hydrogen atom or a C₁₋₁₀ organic group, and n is an integer of from 1 to 200.

The fluorinated polymer (A) may be prepared, for example, by the following method. Firstly, the monomer is dissolved in a solvent and heated, and a polymerization initiator is added to carry out copolymerization to obtain a copolymer. In the copolymerization reaction, a chain transfer agent may preferably be present, as the case requires. The monomer, the polymerization initiator, the solvent and the chain transfer agent may continuously be added.

The above solvent may, for example, be an alcohol such as ethanol, 1-propanol, 2-propanol, 1-butanol or ethylene glycol; a ketone such as acetone, methyl isobutyl ketone or cyclohexanone; a cellosolve such as 2-methoxyethanol, 2-ethoxyethanol or 2-butoxyethanol; a carbitol such as 2-(2-methoxyethoxy)ethanol, 2-(2-ethoxyethoxy)ethanol or 2-(2-butoxyethoxy)ethanol; an ester such as methyl acetate, ethyl acetate, n-butyl acetate, ethyl lactate, n-butyl lactate, ethylene glycol monomethyl ether acetate, propylene glycol monomethyl ether acetate, ethylene glycol diacetate or glycerol triacetate; or an ether such as diethylene glycol dimethyl ether or diethylene glycol methylethyl ether.

As the polymerization initiator, a known organic peroxide, an inorganic peroxide, or an azo compound may, for example, be mentioned. The organic peroxide and the inorganic peroxide may be used in combination with a reducing agent in the form of a redox catalyst. These polymerization initiators may be used alone or in combination as a mixture of two or more of them.

The organic peroxide may, for example, be benzoyl peroxide, lauroyl peroxide, isobutyl peroxide, t-butyl hydroperoxide or t-butyl-α-cumyl peroxide.

The inorganic peroxide may, for example, be ammonium persulfate, sodium persulfate, potassium persulfate, hydrogen peroxide or a percarbonate.

The azo compound may, for example, be 2,2′-azobisisobutyronitrile, 1,1′-azobis(cyclohexane-1-carbonitrile), 2,2′-azobis(2,4-dimethylvaleronitrile), 2,2′-azobis(4-methoxy-2,4-dimethylvaleronitrile), dimethyl 2,2′-azobisisobutyrate or 2,2′-azobis(2-amidinopropane)dihydrochloride.

The chain transfer agent may, for example, be a mercaptan such as n-butylmercaptan, n-dodecylmercaptan, t-butylmercaptan, ethyl thioglycolate, 2-ethylhexyl thioglycolate or 2-mercaptoethanol; or an alkyl halide such as chloroform, carbon tetrachloride or carbon tetrabromide.

The copolymer obtained as described above is reacted with a compound (z1) having a functional group capable of being bonded with the reactive group and an ethylenic double bond to obtain the fluorinated polymer (A).

The following combinations may, for example, be mentioned as a combination of the compound (z1) containing a functional group capable of being bonded with a reactive group and an ethylenic double bond, to the monomer (a2) containing the reactive group.

(1) An acid anhydride (z1) containing an ethylenic double bond to a monomer (a2) having a hydroxyl group.

(2) A compound (z1) containing an isocyanate group and an ethylenic double bond, to a monomer (a2) containing a hydroxyl group.

(3) A compound (z1) containing a chlorinated acyl group and an ethylenic double bond, to a monomer (a2) having a hydroxyl group.

(4) A compound (z1) containing a hydroxyl group and an ethylenic double bond, to an acid anhydride (a2) containing an ethylenic double bond.

(5) A compound (z1) containing an epoxy group and an ethylenic double bond, to a monomer (a2) containing a carboxyl group.

(6) A compound (z1) containing a carboxyl group and an ethylenic double bond, to a monomer (a2) containing an epoxy group.

As specific examples of the acid anhydride containing an ethylenic double bond, the above-mentioned examples may be mentioned.

Specific examples for the compound containing an isocyanate group and an ethylenic double bond, may be 2-(meth)acryloyloxyethyl isocyanate and 1,1-(bis(meth)acryloyloxymethyl)ethyl isocyanate.

As a specific example for the compound containing a chlorinated acyl group and an ethylenic double bond, (meth)acryloyl chloride may be mentioned.

As specific examples for the compound containing a hydroxyl group and an ethylenic double bond, the above-mentioned examples for the monomer containing a hydroxyl group may be mentioned.

As specific examples for the compound containing an epoxy group and an ethylenic double bond, the above-mentioned examples for the monomer containing an epoxy group may be mentioned.

As specific examples for the compound having a carboxyl group and an ethylenic double bond, the above-mentioned examples for the monomer containing a carboxyl group may be mentioned.

When the copolymer is reacted with the compound (z1) containing a functional group capable of being bonded to the reactive group and an ethylenic double bond, the solvent exemplified in the above-described preparation of the copolymer may be used as the solvent to be used for the reaction.

Further, a polymerization inhibitor may preferably be blended. As such a polymerization inhibitor, a conventional polymerization inhibitor may be used, and specifically, 2,6-di-t-butyl-p-cresol may be mentioned.

Further, a catalyst or a neutralizing agent may be added. For example, in a case where a copolymer having a hydroxyl group is to be reacted with a compound containing an isocyanate group and an ethylenic double bond, a tin compound or the like may be used. The tin compound may, for example, be dibutyltin dilaurate, dibutyltin di(maleic acid monoester), dioctyltin dilaurate, dioctyltin di(maleic acid monoester) or dibutyltin diacetate.

In a case where a compound containing a hydroxyl group is to be reacted with a compound containing a chlorinated acyl group and an ethylenic double bond, a basic catalyst may be used. As such a basic catalyst, triethylamine, pyridine, dimethyl aniline or tetramethylurea may, for example, be mentioned.

The content of fluorine atoms in the fluorinated polymer (A) of the present invention is preferably from 5 to 35 mass %. As the content is high, the fluorinated polymer (A) will be excellent in the effect to lower the surface tension of partition walls to be formed, and a high water-and-oil repellency will be imparted to the partition walls. On the other hand, if the content of fluorine atoms is too high, the adhesion between the partition walls and the substrate tends to be low. The content of fluorine atoms in the fluorinated polymer (A) is more preferably such that the lower limit is 10 mass %, and the upper limit is 30 mass %.

The fluorinated polymer (A) preferably contains at least 2 and at most 100, more preferably at least 6 and at most 50, ethylenic double bonds in one molecule. Within such a range, the fluorinated polymer (A) will have good developability and fixing property to partition walls.

The acid value of the fluorinated polymer (A) is preferably at most 100 (mgKOH/g), more preferably from 10 to 50 (mgKOH/g). Within such a range, the residual molecules not fixed in the exposure step will be readily washed off from the partition walls in the development step. Here, the acid value is the mass (unit: mg) of potassium hydroxide required to neutralize 1 g of the resin, and in this specification, the unit is identified by mgKOH/g.

The weight average molecular weight of the fluorinated polymer (A) is preferably at least 1,000 and less than 30,000, more preferably at least 2,000 and less than 20,000. Within such a range, the alkali solubility and the developability are good.

The proportion of the fluorinated polymer (A) in the total solid content of the negative photosensitive composition of the present invention is preferably from 0.1 to 30 mass %, based on the total solid content. When such a proportion is high, the fluorinated polymer (A) will be excellent in the effect to lower the surface tension of the partition walls to be formed, and a high water-and-oil repellency will be imparted to the partition walls. On the other hand, if the proportion is too high, the adhesion between the partition walls and the substrate tends to be low. The proportion of the fluorinated polymer (A) in the total solid content of the composition is preferably such that the lower limit is 0.15 mass %, and the upper limit is 20 mass %.

In the present invention, the negative photosensitive composition preferably contains an alkali-soluble photosensitive resin (B) containing an acidic group and an ethylenic double bond in one molecule. The photosensitive resin (B) preferably contains substantially no fluoroalkyl group.

Such a photosensitive resin (B) may, for example, be a copolymer (B-1) of at least two monomers containing an ethylenic double bond, which has a side chain containing an acidic group and a side chain containing an ethylenic double bond, a novolac resin derivative (B-2) containing an acidic group and an ethylenic double bond in one molecule, and an epoxy resin derivative (B-3) containing an acidic group and an ethylenic double bond in one molecule.

The copolymer (B-1) can be prepared in the same manner as for the above fluorinated polymer (A) except that no monomer (a1) containing a fluoroalkyl group is used.

A novolac resin in the novolac resin derivative (B-2) is one obtained by polycondensation of a phenol with an aldehyde. Specific examples of the phenol may, for example, be phenol, o-cresol, m-cresol, p-cresol, 2,3-xylenol, 2,5-xylenol, 3,5-xylenol, 2,3,5-trimethylphenol, catechol, resorcinol, hydroquinone, methylhydroquinone, pyrogallol and fluoroglycinol. The aldehyde is preferably formaldehyde. The novolac resin may, for example, be a phenol/formaldehyde resin, a cresol/formaldehyde resin or a phenol/cresol/formaldehyde co-condensed resin. Particularly when a photosensitive resin of a cresol/formaldehyde resin type is used, the wettability to ink of the surface of the substrate having the resin removed by development will be good, such being desirable.

As a method for introducing an ethylenic double bond to the above resin, a method may, for example, be mentioned wherein some of phenolic hydroxyl groups are reacted with a compound containing an epoxy group and an ethylenic double bond. Or, a method may be mentioned wherein some or all of phenolic hydroxyl groups are reacted with epichlorohydrin to introduce epoxy groups to a novolac resin, and then, the epoxy groups are reacted with a compound containing a carboxyl group and an ethylenic double bond. Further, hydroxyl groups formed by this reaction may be reacted with an acid anhydride to introduce carboxyl groups into the molecule.

The epoxy resin derivative (B-3) is preferably formed from a bisphenol epoxy compound represented by the formula (3). In the formula, each of R⁷ and R⁸ is independently a hydrogen atom, a C₁₋₅ alkyl group or a halogen atom, Y is —CO—, —SO₂—, —C(CF₃)₂—, —Si(CH₃)₂—, —CH₂—, —C(CH₃)₂—, —O—, a 9,9-fluorenyl group or a single bond, and n is an integer of from 0 to 10.

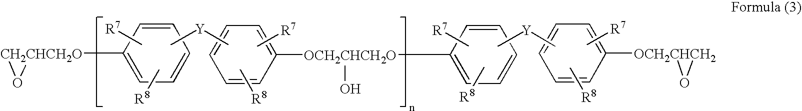

As the bisphenol epoxy compound which gives a preferred epoxy resin derivative (B-3), the following may be mentioned. Namely, a compound including e.g. bis(4-hydroxyphenyl)ketone, bis(4-hydroxy-3,5-dimethylphenyl)ketone, bis(4-hydroxy-3,5-dichlorophenyl)ketone, bis(4-hydroxyphenyl)sulfone, bis(4-hydroxy-3,5-dimethylphenyl)sulfone, bis(4-hydroxy-3,5-dichlorophenyl)sulfone, bis(4-hydroxyphenyl)hexafluoropropane, bis(4-hydroxy-3,5-dimethylphenyl)hexafluoropropane, bis(4-hydroxy-3,5-dichlorophenyl)hexafluoropropane, bis(4-hydroxyphenyl)dimethylsilane, bis(4-hydroxy-3,5-dimethylphenyl)dimethylsilane, bis(4-hydroxy-3,5-dichlorophenyl)dimethylsilane, bis(4-hydroxyphenyl)methane, bis(4-hydroxy-3,5-dichlorophenyl)methane, bis(4-hydroxy-3,5-dibromophenyl)methane, 2,2-bis(4-hydroxyphenyl)propane, 2,2-bis(4-hydroxy-3,5-dimethylphenyl)propane, 2,2-bis(4-hydroxy-3,5-dichlorophenyl)propane, 2,2-bis(4-hydroxy-3-methylphenyl)propane, 2,2-bis(4-hydroxy-3-chlorophenyl)propane, bis(4-hydroxyphenyl)ether, bis(4-hydroxy-3,5-dimethylphenyl)ether or bis(4-hydroxy-3,5-dichlorophenyl)ether, a compound wherein X is the above-mentioned 9,9-fluorenyl group, such as 9,9-bis(4-hydroxyphenyl)fluorene, 9,9-bis(4-hydroxy-3-methylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, 9,9-bis(4-hydroxy-3-methoxyphenyl)fluorene, 9,9-bis(4-hydroxy-3,5-dimethylphenyl)fluorene, 9,9-bis(4-hydroxy-3,5-dichlorophenyl)fluorine or 9,9-bis(4-hydroxy-3,5-dibromophenyl)fluorene, or a compound such as 4,4′-biphenol or 3,3′-biphenol, may be mentioned.

Further, an oligomer may be included when the bisphenol epoxy compound is converted to the glycidyl ether. However, so long as the average value of n in the formula (I) is within a range of from 0 to 10, preferably from 0 to 2, there will be no problem with respect to the performance of the resin composition of the present invention.

As a method for introducing an ethylenic double bond to the above resin, a method may, for example, be mentioned wherein an epoxy group of the bisphenol epoxy compound is reacted with a carboxyl group of the compound containing the carboxyl group and an ethylenic double bond. Further, a hydroxyl group formed by this reaction may be reacted with an acid anhydride to introduce a carboxyl group into the molecule.

The acid value of the photosensitive resin (B) is preferably from 10 to 300 mgKOH/g, more preferably from 30 to 150 mgKOH/g. Within such a range, the alkali solubility and the developability will be good.

The photosensitive resin (B) preferably has at least three ethylenic double bonds in one molecule, preferably at least 6 ethylenic double bonds in one molecule. It is thereby possible that the difference in alkali solubility may readily be made between an exposed portion and a non-exposed portion, and it becomes possible to form a fine pattern with less light exposure.

The number average molecular weight of the photosensitive resin (B) is preferably at least 1,000 and less than 100,000, more preferably at least 4,000 and less than 60,000. Within such a range, the alkali solubility and the developability will be good.

The photosensitive resin (B) preferably further has a carboxyl group and/or a hydroxyl group as a crosslinkable group. In a case where the negative photosensitive composition of the present invention further contains a thermosetting agent (G) which is a compound having at least two groups capable of reacting with a carboxyl group and/or a hydroxyl group, such thermosetting resin undergoes a crosslinking reaction with the photosensitive resin (B) by heat treatment after the development, whereby the crosslinked density of the coating film will increase, and the heat resistance will be improved. The carboxyl group or the phenolic hydroxyl group as an acidic group is also a crosslinkable group. In a case where the photosensitive resin (B) has a sulfonic acid group or a phosphoric acid group, as an acidic group, it is preferred to have at least one of a carboxyl group, a phenolic hydroxyl group and an alcoholic hydroxyl group, as a crosslinkable group.

The proportion of the photosensitive resin (B) in the total solid content in the negative photosensitive composition is preferably from 5 to 80 mass %, more preferably from 10 to 60 mass %, based on the total solid content. Within such a range, the alkali developability of the negative photosensitive composition will be good.

In the present invention, the negative photosensitive composition preferably contains a photopolymerization initiator (C). The photopolymerization initiator (C) is preferably made of a compound which emits radicals by light.

The photopolymerization initiator (C) may, for example, be an α-diketone such as benzyl, diacetyl, methylphenylglyoxylate or 9,10-phenanthrenequinone; an acyloin such as benzoin; an acyloin ether such as benzoin methyl ether, benzoin ethyl ether or benzoin isopropyl ether; a thioxanthone such as thioxanthone, 2-chlorothioxanthone, 2-methylthioxanthone, 2,4-dimethylthioxanthone, isopropylthioxanthone, 2,4-diethylthioxanthone, 2,4-dichlorothioxanthone, 2,4-diisopropylthioxanthone or thioxanthone-4-sulfonic acid; a benzophenone such as benzophenone, 4,4′-bis(dimethylamino)benzophenone or 4,4′-bis(diethylamino)benzophenone; an acetophenone such as acetophenone, 2-(4-toluenesulfonyloxy)-2-phenylacetophenone, p-dimethylaminoacetophenone, 2,2′-dimethoxy-2-phenylacetophenone, p-methoxyacetophenone, 2-methyl-[4-(methylthio)phenyl]-2-morpholino-1-propanone or 2-benzyl-2-dimethylamino-1-(4-morpholinophenyl)-butan-1-on; a quinone such as anthraquinone, 2-ethylanthraquinone, camphorquinone or 1,4-naphthoquinone; an aminobenzoate such as ethyl 2-dimethylaminobenzoate, ethyl 4-dimethylaminobenzoate, (n-butoxy)ethyl 4-dimethylaminobenzoate, isoamyl 4-dimethylaminobenzoate or 2-ethylhexyl 4-dimethylaminobenzoate; a halogen compound such as phenacyl chloride or trihalomethyl phenyl sulfone; an acylphosphineoxide; a peroxide such as di-t-butylperoxide; an oxime ester such as 1,2-octanedione, 1-[4-(phenylthio)-, 2-(o-benzoyloxime) or ethanone 1-[9-ethyl-6-(2-methylbenzoyl)-9H-carbazoyl-3-yl]-1-(o-acetyloxime); an imidazole such as 2,2-bis(2-chlorophenyl)-4,5,4′,5′-tetraphenyl-1,2′-biimidazole; or methyl o-benzoylbenzoate.

Such photopolymerization initiators may be used alone or in combination as a mixture of two or more of them. Particularly, the above-mentioned aminobenzoate, the above-mentioned benzophenone or the like may be used together with another photoradical-forming agent to exhibit a sensitizing effect. Further, an aliphatic amine such as triethanolamine, methyldiethanolamine, triisopropanolamine, n-butylamine, N-methyldiethanolamine or diethylaminoethyl methacrylate may likewise be used together with a photoradical-forming agent to exhibit a sensitizing effect.

The proportion of the photopolymerization initiator (C) in the total solid content in the negative photosensitive composition is preferably from 0.1 to 50 mass %, more preferably from 0.5 to 30 mass %, based on the total solid content. Within such a range, the alkali developability of the negative photosensitive composition will be good.

In the present invention, the negative photosensitive composition preferably further contains a radical crosslinking agent (D), whereby curing by irradiation with light will be accelerated, and curing will be possible in a relatively short time. As the radical crosslinking agent (D), a compound is preferred which is insoluble in alkali and contains at least two ethylenic double bonds. However, it contains substantially no fluoroalkyl group.

Specific examples include, for example, diethylene glycol di(meth)acrylate, tetraethylene glycol di(meth)acrylate, tripropylene glycol di(meth)acrylate, neopentyl glycol di(meth)acrylate, 1,9-nonanediol di(meth)acrylate, trimethylolpropane tri(meth)acrylate, pentaerythritol tri(meth)acrylate, pentaerythritol tetra(meth)acrylate, ditrimethylol propane tetra(meth)acrylate and dipentaerythritol hexa(meth)acrylate. They may be used alone or in combination as a mixture of two or more of them.

The proportion of the radical crosslinking agent (D) in the total solid content in the negative photosensitive composition, is preferably from 10 to 60 mass %, more preferably from 15 to 50 mass %, based on the total solid content. Within such a range, the alkali developability of the negative photosensitive composition will be good.

In the present invention, the negative photosensitive composition preferably contains a thermosetting agent (E), as the case requires. It is thereby possible to improve the heat resistance and water permeation resistance of the photosensitive resin.

The thermosetting agent (E) may, for example, be an amino resin, a compound having at least two epoxy groups, a compound having at least two hydrazino groups, a polycarbodiimide compound, a compound having at least two oxazoline groups, a compound having at least two aziridine groups, a polyvalent metal, a compound having at least two mercapto groups or a polyisocyanate compound.

Among such thermosetting agents (E), an amino resin, a compound having at least two epoxy groups or a compound having at least two oxazoline groups is particularly preferred, whereby chemical resistance of the formed partition walls will be improved.

The proportion of the thermosetting agent (E) in the total solid content in the negative photosensitive composition is preferably from 1 to 50 mass %, more preferably from 5 to 30 mass %, based on the total solid content. Within such a range, the alkali developability of the negative photosensitive composition will be good.

In the present invention, the negative photosensitive composition preferably contains a silane coupling agent (F) as the case requires, whereby it is possible to improve the adhesion with the substrate.

Specific examples of the silane coupling agent may, for example, be tetraethoxysilane, 3-glycidoxypropyltrimethoxysilane, methyltrimethoxysilane, vinyltrimethoxysilane, 3-methacryloyloxypropyltrimethoxysilane, 3-chloropropyltrimethoxysilane, 3-mercaptopropyltrimethoxysilane, heptadecafluorooctylethyltrimethoxysilane, a polyoxyalkylene chain-containing triethoxysilane and imidazole silane. They may be used alone or in combination as a mixture of two or more of them.

In the negative photosensitive composition in the present invention, a diluting agent (G) may be used.

As specific examples of the diluting agent (G), polymerizable monomers exemplified in the description of the fluorinated polymer (A) may be mentioned. Further, solvents exemplified in the description of the solvent to be used for the preparation of the fluorinated polymer (A) may be mentioned. As other examples, a linear hydrocarbon such as n-butane or n-hexane, a cyclic saturated hydrocarbon such as cyclohexane, or an aromatic hydrocarbon such as toluene, xylene or benzyl alcohol may, for example, be mentioned. They may be used alone or in combination as a mixture of two or more of them.

Further, in the negative photosensitive composition of the present invention, a colorant (H) may be used as the case requires, whereby partition walls may be colored.

In a black photosensitive colorant composition to form a black matrix (BM), it is possible to use, for example, carbon black, aniline black, anthraquinone black pigment or perylene black pigment, e.g. specifically, C. I. Pigment Black 1, 6, 7, 12, 20 or 31. In the black photosensitive colorant composition, it is also possible to use a mixture of organic or inorganic pigments of e.g. red, blue and green pigments.

As a black pigment, carbon black is preferred from the viewpoint of the price and good shielding property. Such carbon black may be surface-treated with e.g. a resin. Further, in order to adjust the color tone, a blue pigment or a purple pigment may be used in combination for the black photosensitive colorant composition.

The carbon black is preferably one having a specific surface area of from 50 to 200 m²/g as measured by BET method, from the viewpoint of the black matrix shape. If carbon black having a specific surface area of less than 50 m²/g is used, deterioration of the black matrix shape is likely to result, and if carbon black having a specific surface area exceeding 200 m²/g is used, a dispersing agent is likely to be excessively adsorbed on the carbon black, whereby it will be required to incorporate a large amount of a dispersing agent in order to obtain various physical properties.

Further, the carbon black is preferably one having dibutyl phthalate oil absorption of at most 120 cc/100 g from the viewpoint of the sensitivity. The smaller the oil absorption, the better.

Further, the average primary particle size of carbon black is preferably from 20 to 50 nm as observed by a transmission electron microscope. If the average primary particle size is too small, it tends to be difficult to disperse it at a high concentration and to obtain a photosensitive black composition having good stability with time. If the average primary particle size is too large, deterioration of the black matrix shape is likely to result.

As the red pigment, it is possible to employ, for example, C. I. Pigment Red 7, 9, 14, 41, 48:1, 48:2, 48:3, 48:4, 81:1, 81:2, 81:3, 97, 122, 123, 146, 149, 168, 177, 178, 179, 180, 184, 185, 187, 192, 200, 202, 208, 210, 215, 216, 217, 220, 223, 224, 226, 227, 228, 240, 246, 254, 255, 264, 272 or 279.

As the blue pigment, it is possible to employ, for example, C. I. Pigment Blue 15, 15:1, 15:2, 15:3, 15:4, 15:6, 16, 22, 60, 64 or 80.

As the green pigment, it is possible to employ, for example, C. I. Pigment Green 7 or 36.

To the negative photosensitive composition of the present invention, a curing accelerator, a thickener, a plasticizer, a defoaming agent, a leveling agent, an anti-repellent, an ultraviolet absorber, etc. may be incorporated, as the case requires.

### EXAMPLES

Now, the present invention will be described in further detail with reference to Preparation Examples and Working Examples, but it should be understood that the present invention is by no means thereby restricted. Further, in the following, “parts” and “%” are based on mass, unless otherwise specified.

The weight average molecular weight is a value measured by a gel permeation chromatography method using polystyrene as the standard substance.

The content of fluorine atoms contained in the fluorinated polymer (A) was measured by the following method. A obtained fluorinated resin was completely burned and decomposed at 1,200° C., and the generated gas was absorbed in 50 g of water. The amount of fluoride ions in the obtained aqueous solution was quantified, and the content of fluorine atoms contained in the fluorinated polymer (A) was calculated.

The acid value (mgKOH/g) and the number of ethylenic double bonds per molecule, are theoretical values calculated from the blend proportions of monomers as the raw materials.

Abbreviations of compounds used in the following respective Examples will be shown.

C4FMA: CH₂═C(CH₃)COOCH₂CH₂ (CF₂)₄F,

C6FMA: CH₂═C(CH₃)COOCH₂CH₂ (CF₂)₆F,

DMS: dimethylsilicone chain-containing methacrylate

(manufactured by Shin-Etsu Chemical Co., Ltd., tradename: X-22-174DX),

2HEMA: 2-hydroxyethyl methacrylate,

MAA: methacrylic acid,

AA: acrylic acid,

MMA: methyl methacrylate,

IBMA: isobornyl methacrylate,

2ME: 2-mercaptoethanol,

V70: 2,2′-azobis(4-methoxy-2,4-dimethylvaleronitrile) (manufactured by Wako Pure Chemical Industries, Ltd., tradename: V-70),

MOI: 2-methacryloyloxyethyl isocyanate,

DBTDL: dibutyltin dilaurate,

BHT: 2,6-di-t-butyl-p-cresol,

IR907: radical initiator (manufactured by Ciba Specialty Chemicals K.K., tradename: IRGACURE-907),

IR369: radical initiator (manufactured by Ciba Specialty Chemicals K.K., tradename: IRGACURE-369)

OXE01: 1,2-octaonedione, 1-[4-(phenylthio)-, 2-(o-benzoyloxime)] (manufactured by Ciba Specialty Chemicals K.K., tradename: OXE01),

OXE02: ethanone 1-[9-ethyl-6-(2-methylbenzoyl)-9H-carbazoyl-3-yl]-1-(o-acetyloxime) (manufactured by Ciba Specialty Chemicals K.K., tradename: OXE02),

DEAB: 4,4′-bis(diethylamino)benzophenone,

DETX-S: isopropylthioxanthone (manufactured by NIPPON KAYAKU CO., LTD., tradename: DETX-S),

D310: dipentaerythritol pentaacrylate (manufactured by NIPPON KAYAKU CO., LTD., tradename: KAYARAD D-310),

CCR1115: cresol novolac type epoxy acrylate (manufactured by NIPPON KAYAKU CO., LTD., tradename: CCR-1115; solid content: 60 mass %),

ZFR1492H: bisphenol F-type epoxyacrylate (manufactured by NIPPON KAYAKU CO., LTD., tradename: ZFR-1492H; solid content: 65 mass %),

D310: dipentaerythritol pentaacrylate: (manufactured by NIPPON KAYAKU CO., LTD., tradename: KAYARAD D-310),

157S65: bisphenol A novolac type (manufactured by Japan Epoxy Resins Co., Ltd., tradename: EPIKOTE 157S65),

KBM403: 3-glycidoxypropyltrimethoxysilane (manufactured by Shin-Etsu Chemical Co., Ltd., tradename: KBM-403),

DEGDM: diethylene glycol dimethyl ether,

CB: carbon black (average secondary particle size=120 nm, propylene glycol monomethyl ether acetate solution, CB content: 20 mass %, solid content: 25 mass %),

Organic pigment: mixed organic pigment dispersion (average particle size=80 nm, propylene glycol monomethyl ether acetate solution, organic pigment content: 20 mass %, solid content: 25 mass %).

### Preparation Example 1

### Copolymerization

Into an autoclave having an internal capacity of 1 L and equipped with a stirrer, 556.0 g of acetone, 96.0 g of C6FMA, 4.8 g of MAA, 96.0 g of 2-HEMA, 43.2 g of MMA, 6.2 g of a chain transfer agent 2-ME and 4.5 g of a polymerization initiator V-70 were charged, and polymerized at 40° C. for 18 hours with stirring in a nitrogen atmosphere to obtain a solution of copolymer 1. The weight average molecular weight of copolymer 1 was 5,600.

To the obtained acetone solution of copolymer 1, water was added for reprecipitation for purification, and then reprecipitation for purification was carried out by means of petroleum ether, followed by vacuum drying, to obtain 237 g of copolymer 1.

### Introduction of Ethylenic Double Bonds

Into a glass flask having an internal capacity of 500 mL and equipped with a thermometer, a stirrer and a heating device, 100 g of copolymer 1, 47.7 g of MOI, 0.19 g of DBTDL, 2.4 g of BHT and 100 g of acetone were charged and polymerized at 30° C. for 18 hours with stirring to obtain a solution of fluorinated polymer (A-1). To the obtained acetone solution of fluorinated polymer (A-1), water was added for reprecipitation for purification, and then, recrystallization for purification was carried out by means of petroleum ether, followed by vacuum drying to obtain 135 g of fluorinated polymer (A-1) The weight average molecular weight was 8,800.

### Preparation Examples 2 to 7

### Preparation of Fluorinated Polymers (A-2) to (A-6) and (R-1)

Copolymers 2 to 7 were obtained by polymerization reactions in the same manner as in preparation of copolymer 1 except that mixing of materials (unit: g) was changed as shown in Table 1. Then, fluorinated polymers (A-2) to (A-6) each having a side chain containing an ethylenic double bond, and fluorinated polymer (R-1) having no side chain containing an ethylenic double bond, were obtained by reactions in the same manner as in preparation of fluorinated polymer (A-1) except that mixing of materials (unit: g) was changed as shown in Table 2.

The weight average molecular weight of the obtained fluorinated polymer, the content of fluorine atoms in the fluorinated polymer, the number of ethylenic double bonds (C═C) per molecule and the acid value (mgKOH/g) are shown in Table 2.

TABLE 1

| | Ex. 1 | Ex. 2 | Ex. 3 | Ex. 4 | Ex. 5 | Ex. 6 | Ex. 7 |
|---|---|---|---|---|---|---|---|
| C4FMA | — | — | — | 96 | — | — | — |
| C6FMA | 96 | 120 | 96 | — | 96 | 96 | 96 |
| DMS | — | — | — | — | — | 4.8 | — |
| 2HEMA | 96 | 96 | 96 | 96 | 96 | 96 | — |
| MAA | 4.8 | 9.6 | 24 | 19.2 | 24 | 24 | 9.6 |
| MMA | 43.2 | — | — | — | — | — | 86.4 |
| IBMA | — | 38.4 | 24 | 28.8 | 24 | 19.2 | 48 |
| V70 | 4.5 | 3.5 | 4.2 | 4.3 | 4 | 4.2 | 4.4 |
| 2ME | 6.2 | 6.5 | 6.2 | 9.4 | 4.7 | 6.2 | 6.2 |
| Acetone | 556 | 557 | 556 | 556 | 556 | 556 | 556 |
| Copolymer | 1 | 2 | 3 | 4 | 5 | 6 | 7 |
| Amount of copolymer | 237 | 238 | 236 | 236 | 237 | 237 | 238 |
| obtained (g) | | | | | | | |
| Weight average | 5600 | 5700 | 5900 | 3600 | 8200 | 5700 | 5700 |
| molecular weight | | | | | | | |

TABLE 2

| Introduction of | | | | | | | |
|---|---|---|---|---|---|---|---|
| double bonds | Ex. 1 | Ex. 2 | Ex. 3 | Ex. 4 | Ex. 5 | Ex. 6 | Ex. 7 |
| Copolymer used | 1 | 2 | 3 | 4 | 5 | 6 | 7 |
| Copolymer | 100 | 100 | 100 | 100 | 100 | 100 | 100 |
| MOI | 47.7 | 35.8 | 47.7 | 47.7 | 47.7 | 47.7 | — |
| DBTDL | 0.19 | 0.14 | 0.19 | 0.19 | 0.19 | 0.19 | 0.19 |
| BHT | 2.4 | 1.8 | 2.4 | 2.4 | 2.4 | 2.4 | 2.4 |
| Acetone | 100 | 100 | 100 | 100 | 100 | 100 | 100 |
| Fluorinated polymer | A-1 | A-2 | A-3 | A-4 | A-5 | A-6 | R-1 |
| Amount obtained (g) | 135 | 122 | 134 | 138 | 130 | 129 | 98 |
| Weight average molecular | 8800 | 7800 | 8900 | 5300 | 11800 | 8600 | 5800 |
| weight | | | | | | | |
| Fluorine atom content (%) | 15.0 | 20.1 | 15.5 | 13.6 | 16.2 | 14.9 | 22.4 |
| Number of C═C per | 9.2 | 6.9 | 9.2 | 6.1 | 12.3 | 9.2 | 0 |
| molecule | | | | | | | |
| Acid value (mgKOH/g) | 9 | 19 | 44 | 35 | 44 | 44 | 26 |

### Preparation Example 8

### Preparation of Photosensitive Resin (B-1)

Into an autoclave having an internal capacity of 1 L and equipped with a stirrer, 555.0 g of acetone, 96.0 g of AA, 96.0 g of 2-HEMA, 48.0 g of IBMA, 9.7 g of a chain transfer agent DSH and 7.1 g of a polymerization initiator V-70 were charged, and polymerized at 40° C. for 18 hours with stirring in a nitrogen atmosphere to obtain a solution of polymer 8. The weight average molecular weight of polymer 8 was 9,800.

To the obtained acetone solution of polymer 8, water was added for reprecipitation for purification, and then reprecipitation for purification was carried out by means of petroleum ether, followed by vacuum drying, to obtain 240 g of polymer 8.

Then, into a glass flask having an internal capacity of 300 mL and equipped with a thermometer, a stirrer and a heating device, 100 g of polymer 8, 48.3 g of MOI, 0.19 g of DBTDL, 2.4 g of BHT and 100 g of acetone were charged and polymerized at 30° C. for 18 hours with stirring to obtain a solution of photosensitive resin (B-1).

To the obtained acetone solution of photosensitive resin (B-1), water was added for reprecipitation for purification, and then, reprecipitation for purification was carried out by means of petroleum ether, followed by vacuum drying to obtain 148 g of photosensitive resin (B-1). The weight average molecular weight of photosensitive resin (B-1) was 13,200.

### Preparation of Negative Photosensitive Compositions

Fluorinated polymers (A-1) to (A-6) each having a side chain containing an ethylenic double bond, fluorinated polymer (R-1) having no side chain containing an ethylenic double bond, a photosensitive resin (B), a photopolymerization initiator (C) and, as the case requires, other components, were mixed in the proportions (parts by mass) as identified in Table 3, to prepare negative photosensitive compositions 1 to 8.

### Formation and Evaluation of Partition Walls

Using the negative photosensitive compositions prepared as described above, partition walls were formed on substrates by the methods described in the following Examples 1 to 13. With respect to each substrate having partition walls formed thereon, the developability, the water-and-oil repellency, the chemical resistance and the ink jet (IJ) coating property were measured and evaluated by the following methods. The results are summarized in Table 4.

Developability

One completely developed was identified by 0, and one having a portion not developed was identified by X.

Water-and-Oil Repellency

The water-and-oil repellency was evaluated by the contact angles (degrees) of water and xylene on the surface of a coating film formed on a glass substrate. The contact angle is a angle between the solid surface and the tangent line against the liquid surface at a point where the solid and the liquid are in contact with each other, and it was defined by the angle on the side containing the liquid. The larger the angle, the better the water-and-oil repellency of the coating film. The contact angle of water being at least 950° was represented by ◯; the same contact angle being at least 90° and less than 95° was represented by Δ; and the same contact angle being less than 90° was represented by X. The contact angle of xylene being at least 400 was represented by ◯; the same contact angle being at least 350 and less than 40° was represented by Δ; and the same contact angle being less than 35° was represented by X.

Chemical Resistance

The obtained glass substrate having a partition wall pattern formed was immersed in acetone at 25° C. for 24 hours. One where no change in the shape or thickness of partition walls or no change in the water-and-oil repellency was observed after the immersion, was represented by ◯; one where no change in the shape or thickness of partition walls was observed, but the water-and-oil repellency decreased, was represented by Δ; and one where the partition walls were separated or dissolved, was represented by X.

Ink Jet (IJ) Coating Property

With respect to the obtained glass substrate having a partition wall pattern formed, UV-curable inks containing the respective pigments of R, G and B colors were injected within regions partitioned by the partition walls, by means of an ink jet apparatus to form ink layers thereby to form pixels. The pixel pattern thus obtained was observed by an ultra deep shape measuring microscope (manufactured by KEYENCE CORPORATION). One where a pixel pattern free from color mixing or bleeding between the adjacent pixels, free from non-uniformity in thickness of ink layers within pixels and free from edge leakage, was obtained, was represented by ◯; one where edge leakage and non-uniformity in thickness of the coating film within pixels, were observed, although no color mixing or bleeding between the pixels was observed, was represented by Δ; one where color mixing or bleeding between the pixels was observed was represented by X.

### Example 1

Negative photosensitive composition 1 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 50 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 4,000 mJ/cm² by an ultrahigh pressure mercury lamp, from the partition wall-formed surface side (front side) to obtain a substrate having a pattern formed thereon.

### Example 2

Negative photosensitive composition 2 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 100 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 1,500 mJ/cm² by an ultrahigh pressure mercury lamp, from the rear side of the partition wall-formed surface, and heat treatment was further carried out at 200° C. for one hour to obtain a substrate having a pattern formed thereon.

### Example 3

Negative photosensitive composition 3 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 100 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 2,000 mJ/cm² by an ultrahigh pressure mercury lamp, from the partition wall-formed surface side, and heat treatment was further carried out at 200° C. for one hour, to obtain a substrate having a pattern formed thereon.

### Example 4

Negative photosensitive composition 4 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 200 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 3,000 mJ/cm² by an ultrahigh pressure mercury lamp, from the rear side of the partition wall-formed surface, and heat treatment was further carried out at 200° C. for one hour, to obtain a substrate having a pattern formed thereon.

### Example 5

Negative photosensitive composition 5 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 200 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 3,000 mJ/cm² by an ultrahigh pressure mercury lamp, from the partition wall-formed surface side, and heat treatment was further carried out at 200° C. for one hour, to obtain a substrate having a pattern formed thereon.

### Example 6

Negative photosensitive composition 6 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 200 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 4,000 mJ/cm² by an ultrahigh pressure mercury lamp, from the partition wall-formed surface side, and heat treatment was further carried out at 200° C. for one hour, to obtain a substrate having a pattern formed thereon.

### Example 7

Negative photosensitive composition 2 was applied on a glass substrate having a lattice black matrix (BM) (line=20 μm, lattice space=80 μm×400 μm) preliminarily formed thereon, by means of a spinner and then prebaked at 100° C. for two minutes on a hot plate to form a coating film having a thickness of 2.0 μm.

Then, a mask having a lattice pattern formed (line=16 μm, lattice space=82 μm×402 μm) was placed above the coating film with a gap of 30 μm so that partition walls be formed on the black matrix, followed by irradiation with 100 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 1,000 mJ/cm² by an ultrahigh pressure mercury lamp, from the partition wall-formed surface side, and heat treatment was further carried out at 200° C. for one hour, to obtain a substrate having a pattern formed thereon.

### Example 8

Negative photosensitive composition 1 was applied on a cycloolefin polymer (manufactured by Nippon Zeon Co., Ltd., ZEONOR 1600R) substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 100 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 4,000 mJ/cm² by an ultrahigh pressure mercury lamp, from the partition wall-formed surface side to obtain a substrate having a pattern formed thereon.

### Example 9

Negative photosensitive composition 4 was applied on a cycloolefin polymer (manufactured by Nippon Zeon Co., Ltd., ZEONOR 1600R) substrate having 20 nm of silica laminated thereon by sputtering, by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 200 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 4,000 mJ/cm² by an ultrahigh pressure mercury lamp, from the rear side of the partition wall-formed surface, and heat treatment was further carried out at 150° C. for one hour, to obtain a substrate having a pattern formed thereon.

### Example 10

Negative photosensitive composition 1 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 100 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

### Example 11

Negative photosensitive composition 1 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 200 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, heat treatment was carried out at 200° C. for one hour to obtain a substrate having a pattern formed thereon.

### Example 12

Negative photosensitive composition 7 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 200 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 4,000 mJ/cm² by an ultrahigh pressure mercury lamp, from the rear side of the partition wall-formed surface, and heat treatment was further carried out at 200° C. for one hour, to obtain a substrate having a pattern formed thereon.

### Example 13

Negative photosensitive composition 8 was applied on a glass substrate by means of a spinner and then prebaked at 100° C. for two minutes on a hot plate to form a coating film having a thickness of 2.0 μm.

Then, a mask having a lattice pattern formed (line=20 μm, lattice space=80 μm×400 μm) was placed above the coating film with a gap of 30 μm, followed by irradiation with 200 mJ/cm² by means of an ultrahigh pressure mercury lamp. Then, the substrate was subjected to development treatment at 25° C. for 40 seconds by means of a 0.1 mass % tetramethylammonium hydroxide aqueous solution containing a surfactant, and then washed with water and dried.

Then, it was irradiated with 4,000 mJ/cm² by an ultrahigh pressure mercury lamp, from the rear side of the partition wall-formed surface, and heat treatment was further carried out at 200° C. for one hour, to obtain a substrate having a pattern formed thereon.

TABLE 3

| Negative photosensitive | | | | | | | | | |
|---|---|---|---|---|---|---|---|---|---|
| composition No. | | 1 | 2 | 3 | 4 | 5 | 6 | 7 | 8 |
| Fluorinated polymer (A) | | (A-1) | (A-2) | (A-3) | (A-4) | (A-5) | (A-6) | (R-1) | — |
| or (R) | | 0.66 | 0.29 | 0.56 | 0.65 | 0.62 | 0.99 | 0.66 | — |
| Photosensitive resin | B1 | 39.8 | — | 35.6 | 27.8 | — | — | 39.8 | 39.8 |
| (B) | CCR1115 | — | 57.5 | — | — | — | — | — | — |
| | ZFR1492H | — | — | — | — | 55.9 | 53.1 | — | — |
| Photopolymerization | IR907 | 3.3 | 2.8 | — | — | — | — | 3.3 | 3.3 |
| initiator (C) | IR369 | — | — | 3.3 | 2.5 | — | — | — | — |
| | OXE01 | — | — | — | — | 2.6 | — | — | — |
| | OXE02 | — | — | — | — | — | 1.5 | — | — |
| | DEAB | 1.3 | 1.5 | — | — | — | 0.5 | 1.3 | 1.3 |
| | DETX-S | — | — | 1.6 | 1.3 | 2.1 | — | — | — |
| Radical crosslinking | D310 | 26.5 | 22.9 | 19.2 | 15.0 | 15.6 | 14.8 | 26.5 | 26.5 |
| agent (D) | | | | | | | | | |
| Heat curing agent (E) | 157S65 | — | 11.5 | 5.5 | 4.3 | — | — | — | 10.2 |
| Silane coupling agent | KBM403 | 3.3 | 1.7 | 2.7 | 2.1 | 2.6 | 2.5 | 3.3 | 3.3 |
| (F) | | | | | | | | | |
| Diluent (G) | DEGDM | 175.0 | 152.0 | 155.0 | 111.0 | 108.0 | 93.0 | 175.0 | 175.0 |
| Colorant (H) | CB | — | — | — | — | 63.0 | 83.9 | — | — |
| | Organic | — | — | 26.3 | 85.5 | — | — | — | — |
| | pigment | | | | | | | | |

| | | | | | | | | |
|---|---|---|---|---|---|---|---|---|
| Proportion of fluorinated polymer (A) | 0.89 | 0.38 | 1.00 | 0.85 | 0.41 | 0.65 | 0.89 | 0 |
| or (R) in total solid content (%) | | | | | | | | |

TABLE 4

| | | | EXAMPLE | | | | | | | | |
|---|---|---|---|---|---|---|---|---|---|---|---|
| Ex. No. | | | 1 | 2 | 3 | 4 | 5 | 6 | 7 | 8 | 9 |
| Negative photosensitive composition No. | | | 1 | 2 | 3 | 4 | 5 | 6 | 2 | 1 | 4 |
| Substrate | | | Glass | Glass | Glass | Glass | Glass | Glass | Glass + | ZEONOR | SiO₂ + |
| | | | | | | | | | BM | | ZEONOR |
| Steps | Exposure | Light | 50 | 100 | 100 | 200 | 200 | 200 | 100 | 100 | 200 |
| | | exposure | | | | | | | | | |
| | | (mJ/cm²) | | | | | | | | | |
| | Post- | Direction | Front | Rear | Front | Rear | Front | Front | Front | Front | Front |
| | exposure | Light | 4000 | 1500 | 2000 | 3000 | 3000 | 4000 | 1000 | 4000 | 4000 |
| | | exposure | | | | | | | | | |
| | | (mJ/cm²) | | | | | | | | | |
| | Post- | Temperature | Nil | 200 | 200 | 200 | 200 | 200 | 200 | Nil | 150 |
| | baking | (° C.) | | | | | | | | | |
| | | Time (hr) | | 1 | 1 | 1 | 1 | 1 | 1 | | 1 |
| Physical | Developability | | ◯ | ◯ | ◯ | ◯ | ◯ | ◯ | ◯ | ◯ | ◯ |
| properties | Water-and- | Water | ◯ | ◯ | ◯ | ◯ | ◯ | ◯ | ◯ | ◯ | ◯ |
| | oil repellency | Xylene | ◯ | ◯ | ◯ | ◯ | ◯ | ◯ | ◯ | ◯ | ◯ |
| | Chemical | | ◯ | ◯ | ◯ | ◯ | ◯ | ◯ | ◯ | ◯ | ◯ |
| | resistance | | | | | | | | | | |
| | IJ coating | | ◯ | ◯ | ◯ | ◯ | ◯ | ◯ | ◯ | ◯ | ◯ |
| | property | | | | | | | | | | |

Comparative Example

| | | | | |
|---|---|---|---|---|
| Ex. No. | 10 | 11 | 12 | 13 |

| Negative photosensitive composition No. | | | 1 | 1 | 7 | 8 |
|---|---|---|---|---|---|---|
| Substrate | | | Glass | Glass | Glass | Glass |
| Steps | Exposure | Light exposure | 100 | 100 | 200 | 200 |
| | | (mJ/cm²) | | | | |
| | Post- | Direction Light | Nil | Nil | Front | Front |
| | exposure | exposure (mJ/cm²) | | | 4000 | 4000 |
| | Post- | Temperature (° C.) | Nil | 200 | 200 | 200 |
| | baking | Time (hr) | | 1 | 1 | 1 |
| Physical | Developability | | ◯ | ◯ | ◯ | ◯ |
| properties | Water-and- | Water | ◯ | ◯ | ◯ | X |
| | oil repellency | Xylene | X | ◯ | Δ | X |
| | Chemical | | X | ◯ | Δ | ◯ |
| | resistance | | | | | |
| | IJ coating | | X | Δ | X | X |
| | property | | | | | |

In Example 10, post-exposure and heat-curing were not carried out, whereby the coating film was inferior in the oil repellency, the chemical resistance and the ink jet coating property. In Example 11, post-exposure was not carried out, whereby the ink jet coating property was inferior. In Example 12, a fluorinated polymer having no side chain containing an ethylenic double bond was incorporated, whereby the oil repellency and the chemical resistance were slightly poor, and the ink jet coating property was inferior. In Example 13, no fluorinated polymer was incorporated, whereby the water-and-oil repellency and the ink jet coating property were inferior.

### INDUSTRIAL APPLICABILITY

The process for forming partition walls of the present invention is useful for the formation of partition walls for electronic devices, such as partition walls for a color filter prepared by an ink jet coating system, partition walls for ITO electrodes for a liquid crystal display device, partition walls for an organic EL display device or partition walls for a circuit wiring board.

The entire disclosure of Japanese Patent Application No. 2005-342278 filed on Nov. 28, 2005 including specification, claims and summary is incorporated herein by reference in its entirety.

What is claimed is:

1. A process for forming partition walls, which comprises a step of coating a substrate with a negative photosensitive composition containing a fluorinated polymer (A) having a side chain containing a fluoroalkyl group (which may have an etheric oxygen atom) and a side chain containing an ethylenic double bond, a drying step, an exposure step and a development step in this order, followed by a post-exposure step.

2. The process for forming partition walls according to claim 1, wherein in the post-exposure step, exposure is carried out by means of an ultrahigh pressure mercury lamp or a high pressure mercury lamp.

3. The process for forming partition walls according to claim 1, wherein in the post-exposure step, exposure is carried out with a light exposure of at most 500 mJ/cm² by means of a low pressure mercury lamp.

4. The process for forming partition walls according to claim 1, which has a heat treatment step after the post-exposure step.

5. The process for forming partition walls according to claim 1, wherein the fluorine-atom content in the fluorinated polymer (A) is from 5 to 35 mass %, and the proportion of the fluorinated polymer (A) in the total solid content of the negative photosensitive composition is from 0.1 to 30 mass %.

6. The process for forming partition walls according to claim 1, wherein the fluorinated polymer (A) is a polymer which further has a side chain containing an acidic group.

7. The process for forming partition walls according to claim 1, wherein the negative photosensitive composition contains an alkali-soluble photosensitive resin (B) having an acidic group and an ethylenic double bond in one molecule and a photopolymerization initiator (C).

8. A process for forming a color filter, which comprises, after forming partition walls on the substrate by the process as defined in claim 1, injecting ink by an ink jetting method within regions partitioned by the partition walls, to form pixels.

9. A process for forming an organic EL display device, which comprises, after forming partition walls on the substrate by the process as defined in claim 1, injecting ink by an ink jetting method within regions partitioned by the partition walls, to form pixels.
